(19) United States
(12) Patent Application Publication
(10) Pub. No.: US 2010/0062175 A1
(43) Pub. Date: Mar. 11, 2010

(54) Method for Manufacturing an Optical Waveguide Layer

(76) Inventors: Nancy Bollwahn, Jena (DE); Ulrike Schulz, Jena (DE); Peter Munzert, Jena (DE); Norbert Kaiser, Jena (DE)

Correspondence Address: SLATER & MATSIL, L.L.P., 17950 PRESTON RD, SUITE 1000, DALLAS, TX, 75252-5793, US

(21) Appl. No.: 12/556,155

(22) Filed: Sep. 9, 2009

(30) Foreign Application Priority Data
Sep. 10, 2008 (DE) 10 2008 046 579.8

(51) Int. Cl. C23C 14/08; C23C 14/20

(52) U.S. Cl. 427/529; 427/523; 427/525

(57) ABSTRACT

A method for manufacturing an optical waveguide layer includes a substrate that is prepared, onto which a first part-layer is first grown. Subsequently, a second part-layer of the waveguide layer, consisting of the same material as the first part-layer, is grown on the first part-layer. The second part-layer is bombarded with ions as it grows. The method permits manufacturing optical waveguide layers on temperature-sensitive polymer substrates.

This application claims priority to German Patent Application 10 2008 046 579.8, which was filed Sep. 10, 2008 and is incorporated herein by reference.

### TECHNICAL FIELD

The invention relates to a method for manufacturing an optical waveguide layer.

### BACKGROUND

Layers having waveguide properties are particularly required for what are known as biochips, in particular, for applications in medical diagnostics, for example, for DNA analysis or for the determination of antibodies, and in genetic engineering. An optical waveguide can, in particular, be created by applying a layer that has a higher refractive index to a substrate.

Optical waveguide layers should favorably exhibit low attenuation. When growing such layers on glass, layers having a high refractive index and low attenuation are achieved by applying the coating while the substrate is at a high temperature, so that the natural columnar growth of the layers, which hinders light propagation through the layer, is minimized.

The coating methods used to create optical waveguide layers on glass are generally associated with a high energy input into the substrate, as a result of which the substrate temperature can easily exceed a value of 100° C.

Substrate temperatures of more than 100° C., however, are not suitable for some temperature-sensitive plastic substrates. It would, on the other hand, be desirable to fabricate optical waveguide layers on plastic substrates, as these are considerably more economical to manufacture than glass substrates. In particular, thermoplastics can be processed by hot stamping or injection molding, and the microstructures required for application as biochips can be formed directly.

### SUMMARY

In one aspect, the invention discloses a method for the fabrication of an optical waveguide layer on a substrate permitting manufacturing waveguide layers of high quality with low attenuation on temperature-sensitive substrates, in particular, on plastic substrates.

According to at least one embodiment of the method for the fabrication of an optical waveguide layer, a substrate is prepared, and a first part-layer of the waveguide layer is grown on the substrate. Subsequently a second part-layer of the waveguide layer, comprising or consisting of the same material as the first part-layer, is grown on top of the first part-layer, wherein the second part-layer is bombarded with ions as it grows.

The optical waveguide layer is thus grown on the substrate in two partial steps. During the first partial step of the method, a first part-layer of the waveguide layer is applied to the substrate, and this is favorably not bombarded with ions as it grows. In this way, damage to the substrate, in particular, a plastic substrate, resulting from ion bombardment and the excessive increase in the temperature of the substrate surface that could result from this, is avoided. Only during the second stage of the process during which the second part-layer of the waveguide layer, which comprises or consists of the same material as the first part-layer, is grown, energy is introduced into the growing second part-layer by ion bombardment. The input of energy into the growing layer by means of ion bombardment creates a high quality layer, so that in this way an optical waveguide layer with low attenuation can be fabricated. In particular, attenuation values of less than 5 dB, preferably less than 3 dB, can be achieved on a variety of substrate materials. A composite of substrate and optical waveguide layer manufactured in this way exhibits, furthermore, low intrinsic fluorescence.

Favorably, the ions with which the second part-layer is bombarded during its growth have an energy of between 50 eV and 90 eV inclusive. Ions having energy in this range yield a layer of good quality; in particular, the growing layer is compacted by the ion bombardment, which allows a waveguide layer having low attenuation to be created. The ion energy is, on the other hand, still sufficiently low that damage to the substrate caused by the ion bombardment or by an excessive rise in the substrate temperature does not occur.

The ions with which the second part-layer is bombarded as it grows can, in particular, be ions of argon or oxygen.

Favorably, the temperature of the substrate during the growth of the first part-layer and of the second part-layer does not rise above 80° C. It is particularly favorable if the temperature of the substrate during the growth of the two part-layers of the waveguide layer does not rise above even 60° C.

The method is therefore particularly suitable for growing an optical waveguide layer on a temperature-sensitive substrate. In particular, the substrate may be a polymer substrate. Favorably, the substrate incorporates a cyclo-olefine polymer. Cyclo-olefine polymers feature, in particular, low intrinsic fluorescence, which is advantageous for optical measurement processes in biochip applications. Zeonex and Zeonor are examples of cyclo-olefine polymers. Cyclo-olefine polymers of this sort are temperature-sensitive, and cannot therefore easily be coated with an optical waveguide layer using conventional coating methods.

The waveguide layer that comprises the two part-layers applied one after the other favorably comprises or consists of an inorganic material. In particular, the waveguide layer can contain tantalum pentoxide (Ta₂O₅) or can consist of it. Owing to its relatively high refractive index and its transparency, tantalum pentoxide is very suitable as a material for optical waveguide layers.

The first part-layer of the waveguide layer, which is favorably manufactured without ion bombardment, favorably has a thickness of at least 5 nm, particularly favorably of at least 10 nm. In this way it is possible to ensure that the first part-layer protects the substrate underneath from ion bombardment while the second part-layer is being grown.

It is furthermore favorable if the second part-layer is thicker than the first part-layer, so that the greater proportion of the waveguide layer is manufactured under the influence of energy input through ion bombardment. In this way, a high layer quality is achieved, thus yielding a waveguide layer with low optical attenuation. The thickness of the first part-layer that is manufactured without ion bombardment is favorably selected in such a way that it is sufficient to protect the substrate from ion bombardment while the second part-layer is being grown. Favorably the second part-layer is at least ten times as thick as the first part-layer. The second part-layer can, in particular, have a thickness of 100 nm or more.

The first part-layer of the waveguide layer is favorably grown by thermal evaporation. In particular, it has been found advantageous for the first part-layer of the waveguide layer not to be grown with the aid of electron beam evaporation, as in that case a higher intrinsic fluorescence results in the substrate with the applied waveguide layer than in the case of purely thermal evaporation.

The second part-layer can be grown with the aid of thermal evaporation and/or electron beam evaporation. Favorably, the second part-layer, like the first part-layer, is grown using only thermal evaporation.

The optical waveguide layers manufactured by means of the present method are characterized by good adhesion and by a good resistance to temperatures in the range from −25° C. to +60° C. The waveguide layers also exhibit high resistance to polar solvents.

### BRIEF DESCRIPTION OF THE DRAWINGS

The invention is explained in more detail below with the aid of an exemplary embodiment and in association with FIGS. 1 to 3.

FIG. 1, shows a schematic illustration of a first intermediate step in an exemplary embodiment of the method for manufacturing an optical waveguide layer;

FIG. 2, shows a schematic illustration of a second intermediate step in an exemplary embodiment of the method for manufacturing an optical waveguide layer; and

FIG. 3, shows a schematic illustration of a cross-section through an exemplary embodiment of the optical waveguide layer manufactured using the method.

### DETAILED DESCRIPTION OF ILLUSTRATIVE EMBODIMENTS

Elements that are the same, or that have the same effect, are in each case referred to using the same reference numbers. Neither the elements illustrated nor the relative sizes of the elements should be thought of as being to scale.

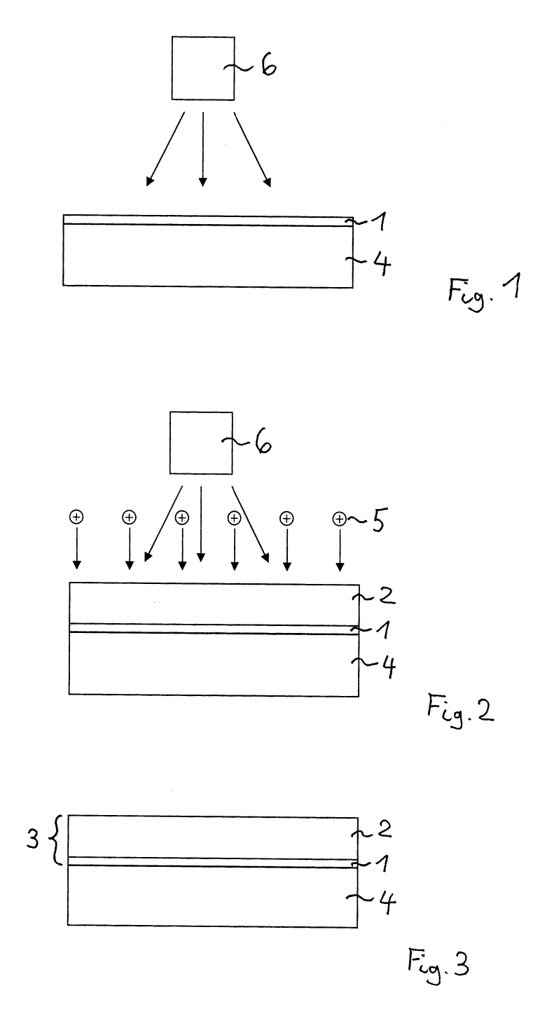

In the first intermediate step illustrated in FIG. 1 of the exemplary embodiment of a method for manufacturing an optical waveguide layer, a first part-layer 1 of the optical waveguide layer is being grown on a substrate 4.

The substrate 4 is favorably a polymer substrate. In particular, the polymer substrate 4 may be a substrate comprising or consisting of a cyclo-olefine polymer, since cyclo-olefine polymers exhibit low intrinsic fluorescence, which is advantageous for applications in biochips.

The optical waveguide layer, of which the first part-layer 1 is applied during the first intermediate step illustrated in FIG. 1, favorably comprising or consisting of an inorganic material. In particular, the waveguide layer can contain Ta₂O₅ or can consist of it.

The material of the first part-layer 1 is favorably applied to the substrate 4 from an evaporation source 6, as suggested by the arrow. The coating process is advantageously carried out in high-vacuum coating equipment, e.g., in coating equipment that permits plasma ion assisted deposition (PIAD). During the coating process, the equipment is favorably evacuated down to a pressure in the range less than 1×10⁻⁶ mbar.

The material that is to be applied is evaporated in the evaporation source 6 from, e.g., a crucible, for instance, a tungsten boat. The crucible is heated for this purpose by, for instance, resistance heating.

The first part-layer 1 is favorably grown by means of thermal evaporation up to a thickness of at least 5 nm on the substrate 4. The first part-layer 1 can, for example, have a thickness of about 10 nm.

In the second partial step of the method, illustrated in FIG. 2, a second part-layer 2 of the optical waveguide layer is grown on top of the first part-layer 1. The second part-layer 2 is manufactured from the same material as the first part-layer 1, for example, from an inorganic material such as, for instance, Ta₂O₅. In contrast to the case of the first part-layer 1, the second part-layer 2 is favorably bombarded with ions 5 as it grows.

The ion bombardment is provided by a plasma ion source (not illustrated). A suitable plasma ion source is, for instance, the APS (Advanced Plasma Source) plasma ion source manufactured by the company Leybold Optics. The ions are accelerated in the direction of the substrate 4 by an adjustable bias voltage. A bias voltage is favorably set to between 50 V and 90 V, in order to bombard the substrate with ion energies of between 50 eV and 90 eV. In particular a value of 80 V, can be set for the bias voltage.

The ions 5 can, for example, be argon and/or oxygen ions. In order to generate the ions, the plasma ion source is supplied with argon or oxygen gas, for instance argon at a flow rate of 14 sccm and oxygen at a flow rate of 20 sccm.

The substrate 4 is protected from the ion bombardment during the growth of the second part-layer 2 by the previously applied first part-layer 1. The temperature of the substrate, furthermore, only rises slightly during the coating process, so that the substrate is also not damaged by a rise in temperature. For example, a temperature of 28° C. is measured at the substrate 4 at the beginning of the coating process, and a temperature of 55° C. at the end.

Like the first part-layer 1, the second part-layer 2 can be created by thermal evaporation from a crucible, for instance from a tungsten boat. The second part-layer 2 can, alternatively, be grown by means of electron beam evaporation. Favorably, however, both the first part-layer 1 and the second part-layer 2 are deposited with the aid of thermal evaporation.

The thickness of the second part-layer 2 is favorably greater than the thickness of the first part-layer 1. In particular, the second part-layer 2 can be at least ten times as thick as the first part-layer 1. The first part-layer 1 can, for example, be grown to a thickness of about 10 nm, while the second part-layer 2 is applied to a thickness of more than 100 nm. The growth rate can, for instance, be 0.23 nm/s. As a result of the ion bombardment during growth of the second part-layer 2, a comparatively dense layer is achieved, characterized by a low attenuation of 5 dB or less.

FIG. 3 illustrates a cross-section of the finished optical waveguide layer 3, comprising the first part-layer 1 and the second part-layer 2, and with the substrate 4 underneath it. The total thickness of the optical waveguide layer can, for instance, be around 150 nm. A sample manufactured with the method described above on the substrate 4 with the waveguide layer 3 applied to it demonstrated fluorescence about 50 percent lower than a sample manufactured using conventional plasma ion aided electron beam evaporation. Furthermore, the optical waveguide layer 3 manufactured using the method described exhibited an attenuation of only around 4 dB for red laser light with a wavelength of 633 nm.

The method is thus particularly suitable for manufacturing optical waveguide layers having low attenuation on temperature-sensitive substrates.

The invention is not restricted to the description that refers to the example embodiments. The invention, rather, comprises every new feature and every combination of features, and, in particular, any combination of features in the patent claims, even if this feature or this combination itself is not explicitly described in the patent claims or in the exemplary embodiments.

What is claimed is:

1. A method of manufacturing an optical waveguide layer, the method comprising:
providing a substrate;
growing a first part-layer of the waveguide layer over the substrate; and
growing a second part-layer of the waveguide layer, on top of the first part-layer, wherein the second part-layer is bombarded with ions as it grows, the first part-layer and the second party-layer consisting of the same material.

2. The method of manufacturing an optical waveguide layer according to claim 1, wherein the ions with which the second part-layer is bombarded as it grows have an energy of between 50 eV and 90 eV.

3. The method of manufacturing an optical waveguide layer according to claim 1, wherein the ions consist of ions of argon and/or oxygen.

4. The method of manufacturing an optical waveguide layer according to claim 1, wherein the substrate has a temperature that does not rise above 80° C. during the growth of the first part-layer and of the second part-layer.

5. The method of manufacturing an optical waveguide layer according to claim 4, wherein the temperature of the substrate during the growth of the first part-layer and of the second part-layer does not rise above 60 C.

6. The method of manufacturing an optical waveguide layer according to claim 1, wherein the substrate is a polymer substrate.

7. The method of manufacturing an optical waveguide layer according to claim 6, wherein the substrate incorporates a cyclo-olefine polymer.

8. The method of manufacturing an optical waveguide layer according to claim 1, wherein the waveguide layer is manufactured from an inorganic material.

9. The method of manufacturing an optical waveguide layer according to claim 1, wherein the waveguide layer contains tantalum pentoxide.

10. The method of manufacturing an optical waveguide layer according to claim 1, wherein the first part-layer has a thickness of at least 5 nm.

11. The method of manufacturing an optical waveguide layer according to claim 1, wherein the second part-layer is thicker than the first part-layer.

12. The method of manufacturing an optical waveguide layer according to claim 11, wherein the second part-layer is at least ten times as thick as the first part-layer.

13. The method of manufacturing an optical waveguide layer according to claim 1, wherein the second part-layer is at least 100 nm thick.

14. The method of manufacturing an optical waveguide layer according to claim 1, wherein growing the first part-layer comprises growing by thermal evaporation.

15. The method of manufacturing an optical waveguide layer according to claim 1, wherein growing the second part-layer comprises growing by thermal evaporation and/or by electron beam evaporation.

16. A method of manufacturing an optical waveguide layer, the method comprising:
providing a polymer substrate;
growing a first part-layer of the waveguide layer over the substrate, the first part-layer comprising tantalum pentoxide; and
growing a second part-layer of the waveguide layer over the first part-layer, wherein the second part-layer is bombarded with argon and/or oxygen ions during the growing, the second part-layer comprising tantalum pentoxide that is thicker than the first part-layer.

17. The method of manufacturing an optical waveguide layer according to claim 16, wherein the ions with which the second part-layer is bombarded as it grows have an energy of between 50 eV and 90 eV.

18. The method of manufacturing an optical waveguide layer according to claim 16, wherein the substrate has a temperature that does not rise above 60 C during the growth of the first part-layer and of the second part-layer.

19. The method of manufacturing an optical waveguide layer according to claim 16, wherein the substrate incorporates a cyclo-olefine polymer.

20. The method of manufacturing an optical waveguide layer according to claim 16, wherein the second part-layer is at least ten times as thick as the first part-layer.
